(19) United States
(12) Patent Application Publication
(10) Pub. No.: US 2025/0240980 A1
(43) Pub. Date: Jul. 24, 2025

(54) SEMICONDUCTOR MEMORY DEVICE

(71) Applicant: Samsung Electronics Co., Ltd., Suwon-si (KR)

(72) Inventors: KEONWOO PARK, Suwon-si (KR); JEONGDON IHM, Suwon-si (KR)

(21) Appl. No.: 19/017,034

(22) Filed: Jan. 10, 2025

(30) Foreign Application Priority Data
Jan. 18, 2024 (KR) 10-2024-0008044

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08145; H01L 2924/1431; H01L 2924/1436

(57) ABSTRACT

Disclosed is a semiconductor memory device which includes a first semiconductor structure and a second semiconductor structure. The first semiconductor structure includes a memory cell array, which is formed in a memory area and includes bit lines and word lines, and a plurality of upper metal pads. The second semiconductor structure is disposed below the first semiconductor structure and includes a plurality of lower metal pads respectively bonded to the plurality of upper metal pads, peripheral circuits disposed under the memory area, and a voltage generator disposed below the memory area and providing an internal voltage to one or more of the peripheral circuits. The upper metal pads are electrically connected to the bit lines or the word lines, and the lower metal pads are electrically connected to terminals of the peripheral circuits.

### CROSS-REFERENCE TO RELATED APPLICATIONS

This application claims priority under 35 U.S.C. § 119 to Korean Patent Application No. 10-2024-0008044 filed on Jan. 18, 2024, in the Korean Intellectual Property Office, the disclosure of which is herein incorporated by reference in its entirety.

### BACKGROUND

Embodiments of the present disclosure described herein relate to a semiconductor device, and more particularly, relate to a semiconductor memory device.

A semiconductor memory may be a volatile memory, which loses data stored therein when power supplied to the memory is turned off, or a non-volatile memory, which retains data when power supplied to the memory is turned off. Volatile memories include static random access memory (SRAM) and dynamic random access memory (DRAM). Nonvolatile memories flash memory, phase-change RAM (PRAM), magnetic RAM (MRAM), resistive RAM (RRAM), and ferroelectric RAM (FRAM).

The DRAM device includes memory cells connected to a word line and a bit line. Through bit lines, the DRAM device stores data in memory cells or reads data stored in memory cells. Through the bit line and the word line, a peripheral circuit may store data in a memory cell or may read the stored data. A voltage generator converts an external voltage (externally supplied to the DRAM) into an internal voltage which is used by circuits of the DRAM. For example, the voltage generator may provide a converted constant voltage to the peripheral circuit. When the power consumption of the peripheral circuit is great, however, a characteristic of the internal voltage output by the voltage generator may become worse.

### SUMMARY

Embodiments of the present disclosure provide a semiconductor memory device in which peripheral circuits are stably provided with an internal voltage and the degree of integration of which is improved.

According to an embodiment, a semiconductor memory device comprises a first semiconductor structure including a first semiconductor substrate, a memory cell array, and a plurality of upper metal pads, the memory cell array being formed in a memory area of the first semiconductor substrate and including bit lines and word lines; and a second semiconductor structure disposed below the first semiconductor structure including a second semiconductor substrate, a plurality of lower metal pads respectively bonded to the plurality of upper metal pads, a peripheral circuit disposed under the memory area, a voltage generator disposed on the lower side of the memory area to provide an internal voltage to the peripheral circuit, wherein the bit lines and the word lines are electrically connected to corresponding ones of the upper metal pads, and wherein some or all of the lower metal pads are electrically connected to terminals of the peripheral circuit.

According to an embodiment, a semiconductor memory device comprises a first semiconductor structure including a first semiconductor substrate, a plurality of sub-memory cell arrays arranged in two dimensions and a plurality of upper metal pads; and a second semiconductor structure disposed below the first semiconductor structure, wherein the second semiconductor structure includes: a second semiconductor substrate; a plurality of lower metal pads bonded to the plurality of upper metal pads; a plurality of peripheral circuits respectively disposed below and electrically connected to respective ones of the plurality of sub-memory cell arrays; and a plurality of voltage generators each disposed below a respective one of the plurality of sub-memory cell arrays to provide an internal voltage to the corresponding peripheral circuit.

According to an embodiment, a semiconductor memory device comprises a first semiconductor substrate; a memory cell array formed in a memory area of the first semiconductor substrate and including a plurality of word lines and a plurality of bit lines; a plurality of upper metal pads formed in the memory area arranged in a two dimensional array; one or more first metal layers electrically connecting first ends of the plurality of word lines or first ends of the plurality of bit lines with corresponding ones of the plurality of upper metal pads; a second semiconductor substrate disposed below the first semiconductor substrate; first bit line sense amplifiers formed in an area of the second semiconductor substrate below the memory cell array, and configured to sense and amplify voltages of corresponding ones of the plurality of bit lines; second bit line sense amplifiers formed in an area of the second semiconductor substrate below the memory cell array, and configured to sense and amplify voltages of corresponding ones of the plurality of bit lines; sub-word line drivers configured to apply voltages to corresponding ones of the plurality of word lines; a voltage generator formed in a first area of the second semiconductor substrate below the memory cell array, and configured to provide an internal voltage to at least one of the first bit line sense amplifiers, the second bit line sense amplifiers, and the sub-word line drivers; a plurality of lower metal pads arranged in a two dimensional array; and one or more second metal layers electrically connecting the first bit line sense amplifiers, the second bit line sense amplifiers, and the sub-word line drivers with corresponding ones of the plurality of lower metal pads, wherein the plurality of upper metal pads and the plurality of lower metal pads are bonded together.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a semiconductor memory device according to an embodiment of the present disclosure.

FIG. 2 is a perspective view illustrating a semiconductor memory device according to an embodiment of the present disclosure.

FIG. 3 is a view illustrating vertical cross sections taken along line A-A′ and line B-B′ of FIG. 2.

FIG. 4 is a diagram illustrating an example of a second semiconductor structure according to an embodiment of the present disclosure.

FIG. 5 is a diagram illustrating a surface of a second semiconductor structure according to an embodiment of the present disclosure.

FIGS. 6A and 6B are diagrams illustrating routing of signals in a first semiconductor structure according to an embodiment of the present disclosure.

FIG. 7 is a diagram illustrating a memory cell array of a first semiconductor structure according to an embodiment of the present disclosure.

FIG. 8 is a diagram illustrating a connection structure of a vertical cross section in a first direction, according to an embodiment of the present disclosure.

FIG. 9 is a diagram illustrating a connection structure of a vertical cross section in a second direction, according to an embodiment of the present disclosure.

FIGS. 10A and 10B are diagrams illustrating placement of a memory cell array and a peripheral circuit according to an embodiment of the disclosure concept.

FIG. 11 is a diagram describing an integrated circuit device.

FIG. 12 is a diagram illustrating a pads array of an integrated circuit device of FIG. 11.

FIG. 13 is a diagram illustrating a vertical cross section of an integrated circuit device taken along line A-A′ of FIG. 12.

FIG. 14 is a diagram illustrating a vertical cross section of an integrated circuit device taken along line B-B′ of FIG. 12.

### DETAILED DESCRIPTION

Below, embodiments of the present disclosure will be described in detail and clearly to such an extent that an ordinary one in the art easily carries out the present disclosure.

Hereinafter, embodiments in the example embodiment will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

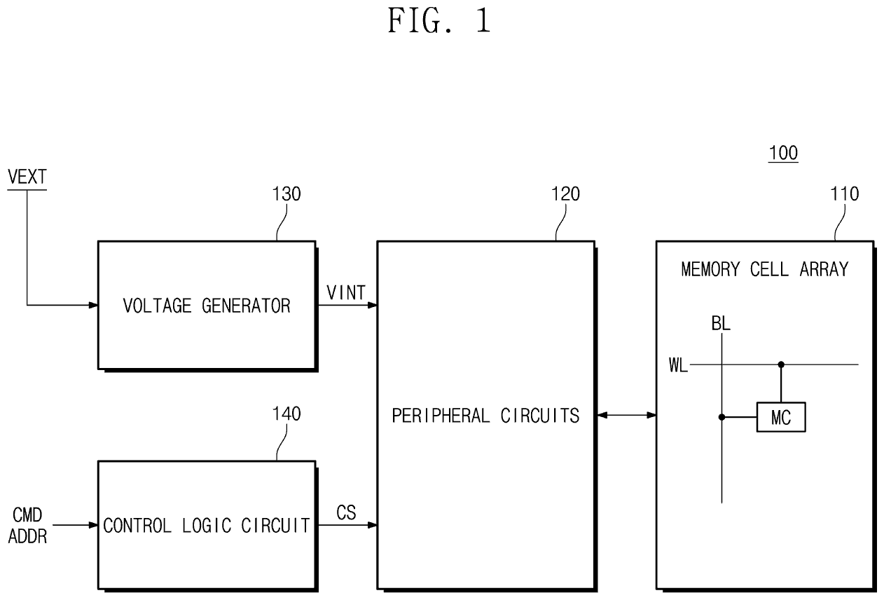

FIG. 1 is a block diagram illustrating a semiconductor device according to an embodiment of the present disclosure. Referring to FIG. 1, a semiconductor memory device 100 may include a memory cell array 110, a peripheral circuits 120, a voltage generator 130, and a control logic circuit 140. Like all the semiconductor devices disclosed herein, the semiconductor memory device 100 may be a semiconductor chip. Such a semiconductor chip may be a semiconductor device singulated from (e.g., cut from) a wafer (which wafer may be formed with one base substrate (e.g., a bulk silicon substrate, a bulk germanium substrate, silicon on insulator (SOI), etc.), e.g., or formed with a combination of several component wafers each having a corresponding base substrate).

The semiconductor memory device 100 may be a dynamic random access memory (DRAM), a double data rate 4 (DDR4) synchronous DRAM (SDRAM), a low power DDR4 (LPDDR4) SDRAM, an LPDDR5 SDRAM, a graphics double data rate5 (GDDR5) SDRAM, a GDDR6 SDRAM, and/or a high bandwidth memory (HBM) such as an HBM2, an HBM2E, and/or an HBM3, but the present invention is not limited thereto.

The memory cell array 110 may include a plurality of word lines WL, a plurality of bit lines BL, and memory cells MC connected to the word lines WL and the bit lines BL. Each of the memory cells MC may include a selection transistor and a storage capacitor. The selection transistor may be connected between the storage capacitor and the bit line BL and may operate in response to a voltage of the word line WL. The storage capacitor may be connected to the selection transistor and may store data depending on an operation of the selection transistor and a level of the bit line BL. The plurality of memory cells MC may be grouped into sub-memory cell arrays.

The peripheral circuits 120 may include a plurality of circuits for operations of the semiconductor memory device 100, such as operations of writing, reading, and managing data associated with the memory cells MC. For example, the peripheral circuits 120 may include a row decoder, a column decoder, an input/output circuit, etc. The row decoder may be connected to the memory cell array 110 through the plurality of word lines WL. The row decoder may decode a row address provided from an external device (a device external to the semiconductor memory device 100, such as a memory controller) and may control voltages of the plurality of word lines WL based on a result of the decoding. The column decoder may be connected to the memory cell array 110 through the plurality of bit lines BL. The column decoder may decode a column address provided from the external device (e.g., a memory controller) and may control the plurality of bit lines BL based on a result of the decoding. The input/output circuit may transmit data to the external device (e.g., a memory controller) or may receive data from the external device. The input/output circuit may provide the data received from the external device to a sense amplifier and/or write driver or may provide the data received from the sense amplifier and/or write driver to the external device.

The peripheral circuits 120 may further include a bit line sense amplifier and a sub-word line driver. The bit line sense amplifier may be electrically connected to the bit line BL of the memory cell array 110 and may sense and amplify a voltage of the bit line BL (e.g., a voltage difference between a bit line BL and a complementary bit line). The sub-word line driver may be electrically connected to the word line WL of the memory cell array 110 and may apply a word line driving voltage to the connected word line WL. As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

The voltage generator 130 may convert an external voltage VEXT input thereto into an internal voltage VINT to be used by the peripheral circuits 120. For example, the voltage generator 130 may generate an internal voltage which is used by at least one of the row decoder, the column decoder, the input/output circuit, the bit line sense amplifier, or the sub-word line driver. The internal voltage VINT corresponds to a constant (e.g., non-fluctuating) voltage which is used in the operation of the peripheral circuits 120. The voltage generator 130 may generate one or more internal voltages which are used by the peripheral circuits 120. For example, when the peripheral circuits 120 operates, a plurality of internal (constant) voltages may be generated by the voltage generator and provided to the peripheral circuits 120 for its use. In this case, the voltage generator 130 may convert the external voltage VEXT into a plurality of internal voltages, and the levels of such internal voltages may be different from one another. The plurality of internal voltages thus converted may be respectively provided to respective circuits included in the peripheral circuits 120. Each of the circuits of the peripheral circuits 120 may operate based on control signals provided thereto and on or more of the provided internal voltages.

The external voltage VEXT supplied to the voltage generator 130 may be provided by a device external to the semiconductor memory device 100. Thus, the voltage generator 130 may have one or more electrical connections (e.g., wires or interconnects formed of patterned metal layers and/or vias) to one or more chip pads (terminals of the semiconductor memory device 100), which in turn may be connected to an external device to receive the external voltage VEXT. In addition, several external voltages VEXT (of the same or different voltage levels) may be provided in the way from an external device to the voltage generator 130 to be used by the voltage generator 130 to generate one or more internal voltages.

The control logic circuit 140 may control the operation of the semiconductor memory device 100. For example, the control logic circuit 140 may generate one or more control signals CS such that the semiconductor memory device 100 performs the write or read operation. The control logic circuit 140 may include a command decoder which decodes a command CMD received from an external device (e.g., a memory controller) and a mode setting register for setting an operation mode of the semiconductor memory device 100. In response to the control signals CS, the peripheral circuits 120 may store data in the memory cell array 110 or may read data from the memory cell array 110.

The semiconductor memory device 100 may have a cell on peri (CoP) structure in which some or all of the peripheral circuits 120 is disposed under the memory cell array 110 (or is disposed in an area on a lower side of the memory cell array 110). As the CoP structure is applied to the semiconductor memory device 100, the storage capacity of the semiconductor memory device 100 may increase, and the utilization of space may be improved.

When a relatively large amount of power consumption occurs in the peripheral circuits 120, the level of the internal voltage may temporarily drop (e.g., a transient voltage dip). Such transient voltage dips in the internal voltage may cause a reduction of operation reliability and performance of the semiconductor memory device 100. However, by forming the semiconductor memory device 100 with a CoP structure, the voltage generator 130 may be disposed to be relatively close to the peripheral circuits 120 and thus, the supply path of an internal voltage to the peripheral circuits 120 may be made relatively short. For example, the peripheral circuits 120 and the voltage generator 130 may be disposed under a memory area to be adjacent to each other. According to the above configuration/structure, the voltage generator 130 may stably provide the internal voltage to the peripheral circuits 120, and the degree of integration of the semiconductor memory device 100 may be improved.

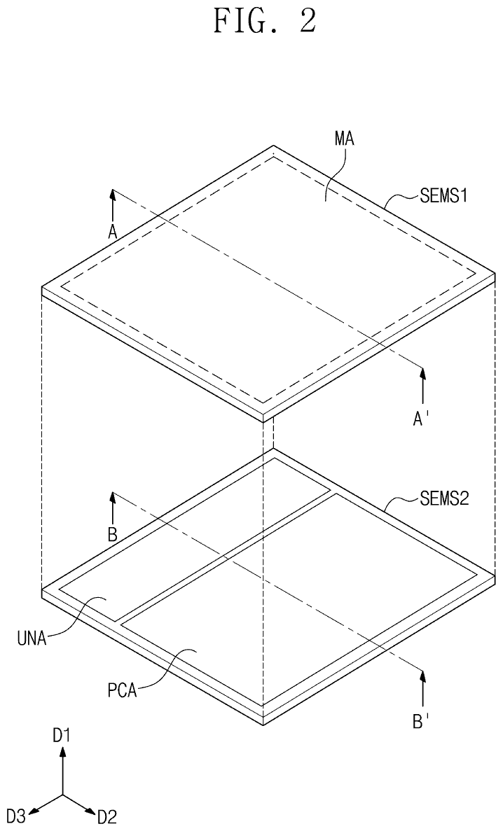

FIG. 2 is a perspective view illustrating a semiconductor memory device according to an embodiment of the present disclosure. Referring to FIG. 2, the semiconductor memory device 100 may include a first semiconductor structure SEMS1 and a second semiconductor structure SEMS2.

The first semiconductor structure SEMS1 may include a memory area MA. A memory cell array which includes a plurality of bit lines and a plurality of word lines may be formed in the memory area MA. The bit lines and the word lines included in the memory cell array may be electrically connected to respective upper metal pads (not illustrated).

The second semiconductor structure SEMS2 may be disposed under (or on the lower side of) the first semiconductor structure SEMS1. The second semiconductor structure SEMS2 may include an unused area UNA and a peripheral circuit area PCA. As will be appreciated, the unused area UNA may include circuits used to operate the semiconductor memory device and the area UNA may correspond to a corresponding area in a conventional semiconductor memory device that was unused. The unused area UNA and the peripheral circuit area PCA correspond to an area (hereinafter, referred to as a “lower-side area”) on the lower side of the memory area MA. Peripheral circuits may be disposed in the peripheral circuit area PCA. For example, bit line sense amplifiers and sub-word line drivers may be disposed in the peripheral circuit area PCA. The peripheral circuits disposed in the peripheral circuit area PCA may be electrically connected to lower metal pads (not illustrated). For example, the bit line sense amplifiers and the sub-word line drivers may be electrically connected to respective lower metal pads.

The lower-side area may correspond to an area projected vertically downward from a specific area included in a first plane. It is assumed that the first plane includes a first area, the first plane is parallel to a second plane, and the second plane includes a second area. That the second area is located in the lower-side area of the first area means that the second area is located in an area projected vertically downward from the first area.

Upper metal pads of the first semiconductor structure SEMS1 and lower metal pads of the second semiconductor structure SEMS2 may be disposed in the form of a matrix array including a plurality of rows and a plurality of columns. The first semiconductor structure SEMS1 and the second semiconductor structure SEMS2 may be bonded together by bonding the upper metal pads to the lower metal pads.

As the pitch from the upper metal pad(s) to the lower metal pad(s) decreases or as the number of memory cells per word line on the memory cell array and the number of memory cells per bit line on the memory cell array increase, redundant upper and lower metal pads may exist. That is, upper metal pads which are not connected to any one of the bit lines and the word lines may exist. Likewise, lower metal pads which are not connected to the peripheral circuit may exist. The unused area UNA may be an area where the upper and lower metal pads not connected to the bit lines, the word lines, and the peripheral circuit are disposed.

In the present disclosure, a first direction D1 is expressed as a direction associated with an upper side (e.g. extending upwards, away from and perpendicular to an upper side), and a direction facing away from the first direction D1 is expressed as a direction associated with a lower side. However, in the present disclosure, the upper/lower expressions “upper side” and “lower side” are provided only for describing a relative location of components, and the present invention is not limited thereto. For example, the second semiconductor structure SEMS2 may be disposed over (or on an upper side of) the first semiconductor structure SEMS1.

The voltage generator 130 of FIG. 1 may be disposed in the unused area UNA included in the second semiconductor structure SEMS2. In some examples, voltage generator 130 may be the only circuit in the unused area UNA. An external voltage may be applied to the voltage generator 130 disposed in the unused area UNA, and the voltage generator 130 may convert the external voltage into an internal voltage to be used by the peripheral circuit. The internal voltage generated by the voltage generator 130 is provided to the peripheral circuit disposed in the peripheral circuit area PCA. The peripheral circuits 120 may operate by using the internal voltage generated by the voltage generator 130. For example, the peripheral circuits 120 may drive the word lines or the bit lines included in the memory cell array depending on the received control signal(s) and internal voltage(s). The peripheral circuits 120 may drive the word lines or the bit lines of the memory cell array to write data received from the outside in memory cells or to read the data stored in the memory cells. Driving a word line may constitute applying an appropriate voltage to the word line such that the selection transistors of the memory cells connected to the word line (e.g., having gates connected to or formed of the word line) turn on. Driving a bit line may constitute applying an appropriate voltage to the bit line to supply appropriate data to an accessed memory cell connected to the bit line, or may constitute precharging the bit line.

As a voltage generator and a peripheral circuit included in a second semiconductor structure are disposed below the memory cell array, the horizontal area of the semiconductor memory device may be reduced, and the degree of integration may be improved in terms of a horizontal size. Also, as the voltage generator and the peripheral circuit are disposed to be relatively close to each other (or are respectively disposed in relatively close areas), the supply path of the internal voltage from the voltage generator to the peripheral circuit may be reduced and the supply of the internal voltage may be improved. Accordingly, it is possible to stably provide the internal voltage.

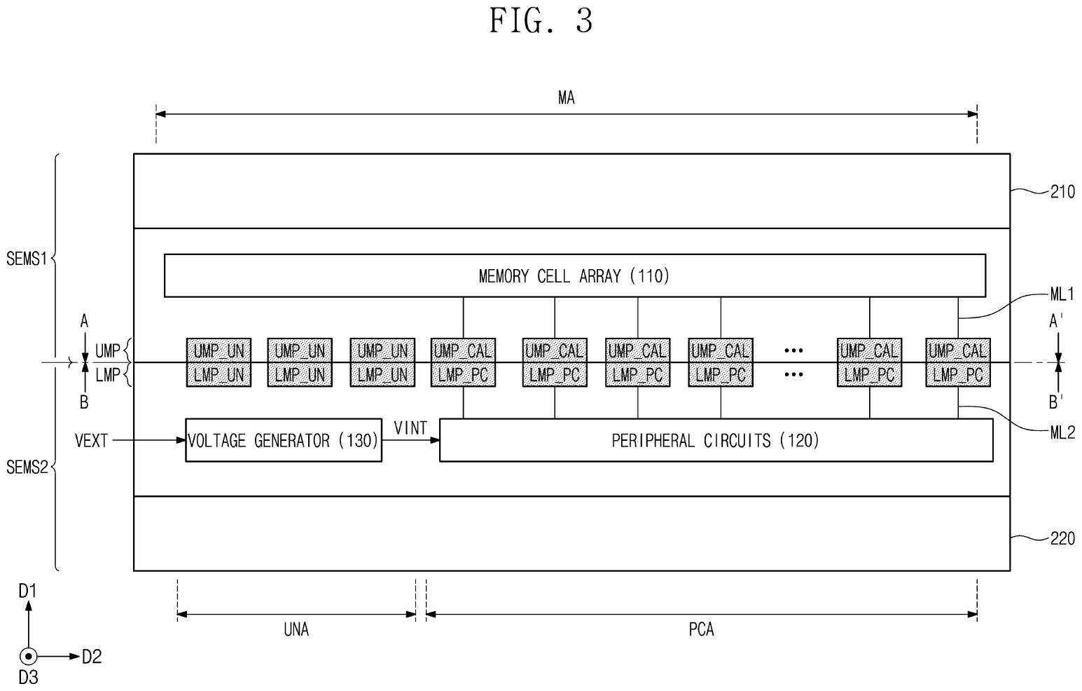

FIG. 3 is a view illustrating vertical cross sections taken along line A-A′ and line B-B′ of FIG. 2. Referring to FIG. 3, the memory cell array 110 may be disposed in the memory area MA of the first semiconductor structure SEMS1.

The first semiconductor structure SEMS1 may include a first semiconductor substrate 210, the memory cell array 110, and a plurality of upper metal pads UMP. The memory cell array 110 may include word lines, bit lines, and memory cells formed at intersections of the word lines and the bit lines. The memory cell array 110 may be formed in and/or on the first semiconductor substrate 210. The first semiconductor substrate 210 may be a base semiconductor substrate formed of or including a layer of a crystalline semiconductor (e.g., bulk silicon substrate, bulk germanium substrate, SOI, etc.). The plurality of upper metal pads UMP may be formed at the surface of the first semiconductor structure SEMS1. The memory cell array 110 and some of the upper metal pads UMP may be electrically connected through first metal lines ML1. The first metal line ML1 may be formed in at least one metal layer. For example, a metal line ML1 may be formed by connecting metal patterns formed of different metal layers with one or more conductive vias.

The plurality of upper metal pads UMP may include unused upper metal pads UMP_UN and connected upper metal pads UMP_CAL. The connected upper metal pads UMP_CAL may be electrically connected to components of the memory cell array 110. For example, the connected upper metal pads UMP_CAL may be connected to the memory cell array 110 through the first metal lines ML1. As an example, each of the connected upper metal pads UMP_CAL may be connected to a respective one of the word lines and or a respective one of the bit lines included in the memory cell array 110 through a corresponding first metal line ML1.

The unused upper metal pad UMP_UN is a metal pad which corresponds to an isolated metal pad and is not electrically connected to any one of the word lines and the bit lines. Each of the unused upper metal pads UMP_UN may form all or part of a corresponding electrical node that is electrically floating.

The second semiconductor structure SEMS2 is disposed under (or on the lower side of) the first semiconductor structure SEMS1. The second semiconductor structure SEMS2 may include a second semiconductor substrate 220, the peripheral circuits 120, the voltage generator 130, and a plurality of lower metal pads LMP. The second semiconductor substrate 220 may be a base semiconductor substrate formed of or including a layer of a crystalline semiconductor (e.g., bulk silicon substrate, bulk germanium substrate, SOI, etc.). The unused area UNA and the peripheral circuit area PCA may be located in the second semiconductor structure SEMS2. The unused area UNA and the peripheral circuit area PCA correspond to the lower-side area of the memory area MA. The peripheral circuits 120 may be disposed in the peripheral circuit area PCA of the second semiconductor structure SEMS2. The peripheral circuits 120 may include circuits, which are necessary to operate the memory cell array 110, such as bit line sense amplifiers and sub-word line drivers. The peripheral circuits 120 may be formed on and/or in the second semiconductor substrate 220. The plurality of lower metal pads LMP may be formed on the surface of the second semiconductor structure SEMS2. The peripheral circuits 120 and some of the lower metal pads LMP may be electrically connected through second metal lines ML2. The second metal line ML2 may be formed in at least one metal layer. Each of the first and second semiconductor substrates 210, 220 may be a base semiconductor substrate (e.g., an initial semiconductor substrate forming the base of the wafer in the final wafer product, such as a bulk semiconductor substrate (e.g., crystalline silicon), a silicon on insulator (SOI) substrate, etc.).

The plurality of lower metal pads LMP may include unused lower metal pads LMP_UN and connected lower metal pads LMP_PC. The unused lower metal pads LMP_UN are lower metal pads disposed in the unused area UNA, and the connected upper metal pads LMP_PC are lower metal pads disposed in the peripheral circuit area PCA. The connected lower metal pads LMP_PC may be electrically connected to the peripheral circuits 120. For example, the connected lower metal pads LMP_PC may be connected to the peripheral circuits 120 through the second metal lines ML2. As an example, the connected lower metal pad LMP_PC may be connected to one of the bit line sense amplifier or the sub-word line driver included in the peripheral circuits 120 through the second metal line ML2.

The unused lower metal pad LMP_UN is a metal pad which corresponds to an isolated metal pad and is electrically disconnected from the peripheral circuits 120. Each of the unused lower metal pads LMP_UN may form all or part of a corresponding electrical node that is electrically floating. The unused lower metal pads LMP_UN may be dummy pads. A voltage generator may be disposed under the unused lower metal pad LMP_UN. In some examples, a group of unused lower metal pads LMP_UN may be confined to a first area in which there are no connected lower metal pads LMP_PC, and the voltage generator 130 may be formed within the boundaries of the first area with respect to a top down view (i.e., formed within the footprint of the first area). This first area may correspond to (e.g., form all or part of) the unused area UNA described herein.

The lower and upper metal pads LMP and UMP may have the same size and the same arrangement (e.g., having a one to one correspondence with respect to a top down view). The lower and upper metal pads LMP and UMP may include, for example, copper (Cu), aluminum (Al), nickel (Ni), cobalt (Co), tungsten (W), titanium (Ti), tin (Sn), or an alloy thereof.

The semiconductor memory device 100 may have a structure in which metal pads of the first semiconductor structure SEMS1 and the second semiconductor structure SEMS2 are bonded together. The upper metal pads UMP of the first semiconductor structure SEMS1 and the lower metal pads LMP of the second semiconductor structure SEMS2 may be connected to each other electrically and physically through bonding. That is, the lower metal pads LMP and the upper metal pads UMP may contact each other. The peripheral circuits 120 and the memory cell array 110 may be electrically connected by the bonding of the lower and upper metal pads LMP and UMP. The peripheral circuits 120 may write data in a memory cell or may read the data stored in the memory cell, by controlling the word lines and the bit lines through the second metal lines ML2, the connected lower metal pads LMP_PC, the connected upper metal pads UMP_CAL, and the first metal lines ML1.

The unused lower metal pads LMP_UN may be disposed in the unused area UNA of the second semiconductor structure SEMS2, and the unused upper metal pads UMP_UN may be disposed in an area corresponding to the unused area UNA from among the memory area MA of the first semiconductor structure SEMS1. The voltage generator 130 may be disposed in the unused area UNA of the second semiconductor structure SEMS2. The voltage generator 130 may receive the external voltage VEXT and may convert the external voltage VEXT into the internal voltage VINT to be used by the peripheral circuits 120. The internal voltage VINT which is a preset constant voltage may include a plurality of voltage levels. The voltage generator 130 may provide the internal voltage VINT to the peripheral circuits 120. The internal voltage VINT which the voltage generator 130 generates may include a plurality of voltage levels depending on the purpose of the internal voltage VINT. That is, the voltage generator 130 may provide the peripheral circuits 120 with the internal voltage VINT including one or more voltage levels.

The voltage generator 130 may be disposed in the unused area UNA adjacent to the peripheral circuit area PCA from among the lower-side area of the memory area MA and may provide the internal voltage VINT at a short distance from the peripheral circuits 120. When power consumption associated with the internal voltage transiently increases due to the operation of the peripheral circuits 120, the transient voltage dips of the internal voltage may be caused. The transient voltage dips act as an obstacle to the operation of the peripheral circuits 120. Assuming that the voltage generator 130 is disposed relatively far apart from the peripheral circuits 120, when the transient voltage dips occur, it is relatively difficult to supply the internal voltage to the peripheral circuits 120. This may cause a relatively great voltage drop. Accordingly, the relatively great voltage drop due to the transient voltage dips may make it difficult to guarantee the normal operation of the peripheral circuits 120.

According to the semiconductor memory device 100 of the present disclosure, the voltage generator 130 may be disposed at a location relatively close to the peripheral circuits 120, the voltage generator 130 may easily supply a voltage to the peripheral circuits 120, and the transient voltage dips due to the power consumption of the peripheral circuits 120 may be improved. Accordingly, the performance of operation of the peripheral circuits 120 may be improved.

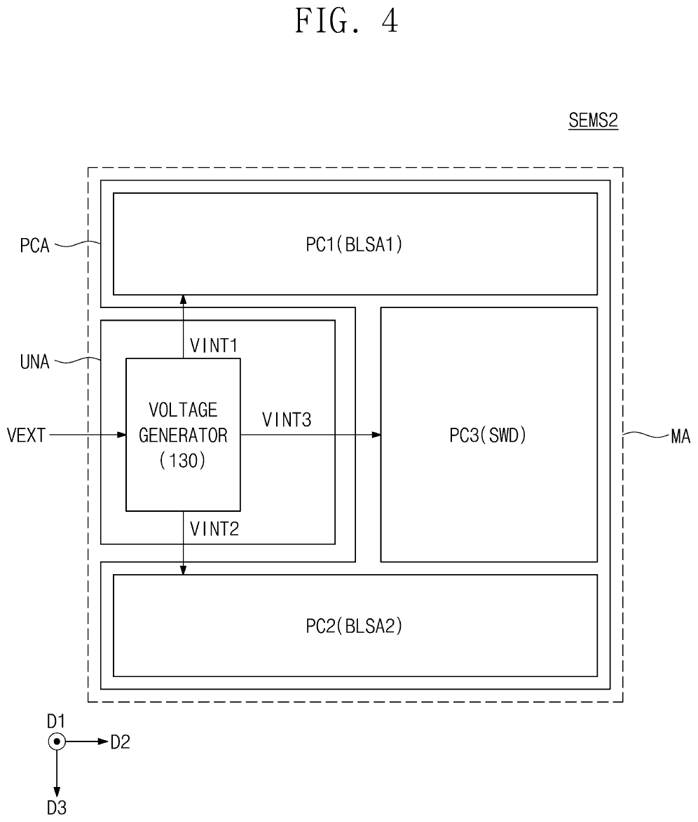

FIG. 4 is a diagram illustrating an example of a second semiconductor structure according to an embodiment of the present disclosure. Referring to FIG. 4, the second semiconductor structure SEMS2 may include the unused area UNA and the peripheral circuit area PCA.

The unused area UNA and the peripheral circuit area PCA of the second semiconductor structure SEMS2 may correspond to the lower-side area of the memory area MA of the first semiconductor structure SEMS1. The peripheral circuit area PCA may be disposed to include three of sides of the lower-side area of the memory area MA, and the unused area UNA may be located in the remaining area other than the peripheral circuit area PCA and may be disposed to be surrounded by the peripheral circuit area PCA. In this case, the unused area UNA may be disposed such that three of sides of the unused area UNA are adjacent to the peripheral circuit area PCA.

A first peripheral circuits PC1 may be disposed on a first side portion of the peripheral circuit area PCA, which is close to a first side of the peripheral circuit area PCA. A second peripheral circuits PC2 may be disposed on a second side portion of the peripheral circuit area PCA, which is close to a second side and opposite to the first side. A third peripheral circuits PC3 may be disposed between the first side portion and the second side portion of the peripheral circuit area PCA. The first peripheral circuits PC1 may include a first bit line sense amplifier BLSA1, and the second peripheral circuits PC2 may include a second bit line sense amplifier BLSA2. The first bit line sense amplifier BLSA1 may be connected to one-half of the bit lines included in the memory cell array, and the second bit line sense amplifier BLSA2 may be connected to the other half of the bit lines. The first bit line sense amplifier BLSA1 and the second bit line sense amplifier BLSA2 may control the bit lines of the memory cell array and may sense and amplify voltage levels of the bit lines. The third peripheral circuits PC3 may include a sub-word line driver SWD. The sub-word line driver SWD may be connected to the word lines included in the memory cell array and may apply a word line driving voltage to each of the word lines.

The voltage generator 130 may be disposed in the unused area UNA One or more external voltages VEXT are applied to the voltage generator 130. The external voltage VEXT which is a voltage input from the outside of the semiconductor memory device 100 may a positive or negative voltage or an external ground voltage. The voltage generator 130 may convert the external voltage(s) VEXT into a first internal voltage VINT1 to be used by the first peripheral circuits PC1, a second internal voltage VINT2 to be used by the second peripheral circuits PC2, and a third internal voltage VINT3 to be used by the third peripheral circuits PC3. The voltage generator 130 may provide the first internal voltage VINT1 to the first peripheral circuits PC1, may provide the second internal voltage VINT2 to the second peripheral circuits PC2, and may provide the third internal voltage VINT3 to the third peripheral circuits PC3. Each of the first to third internal voltages VINT1 to VINT3 may include at least one voltage level. The voltage levels respectively included in the first to third internal voltages VINT1 to VINT3 are used in operations of the first to third peripheral circuits PC1 to PC3.

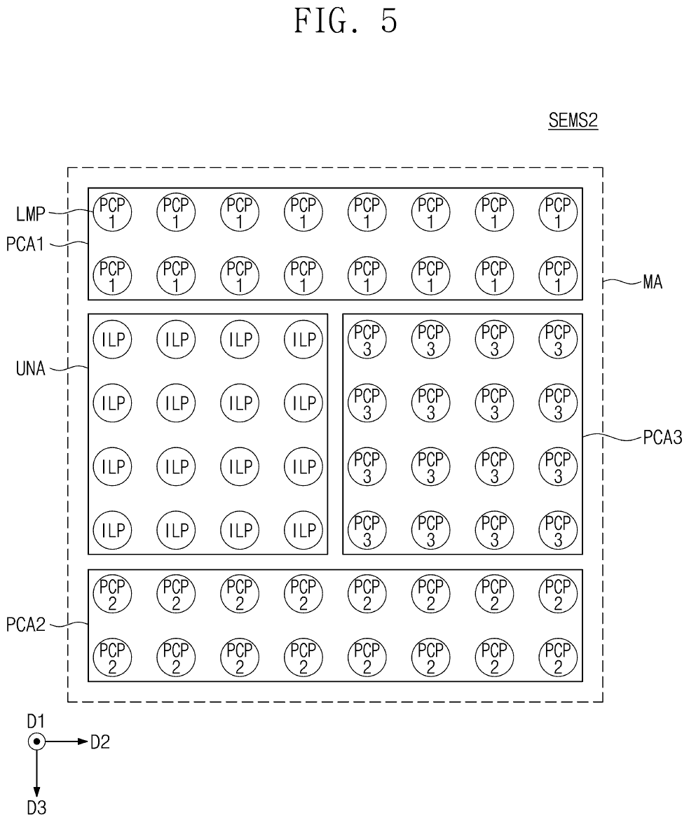

FIG. 5 is a diagram illustrating a surface of a second semiconductor structure according to an embodiment of the present disclosure. Referring to FIG. 5, the second semiconductor structure SEMS2 may include a first peripheral circuit area PCA1, a second peripheral circuit area PCA2, a third peripheral circuit area PCA3, and the unused area UNA.

The plurality of lower metal pads LMP may be disposed at the surface of the second semiconductor structure SEMS2 in the form of a matrix array including a plurality of rows and a plurality of columns of lower metal pads LMP. The example of FIG. 5 illustrates the plurality of lower metal pads LMP of the form of a matrix array with 8 rows and 8 columns, but in the matrix array, the number of rows and the number of columns may be more or less.

The lower metal pads LMP disposed at the surface of the first peripheral circuit area PCA1 of the second semiconductor structure SEMS2 may be electrically connected to the first peripheral circuits PC1. For example, the first peripheral circuit area PCA1 may be an area including the lower metal pads LMP belonging to the first row and the second row of the matrix array of the lower metal pads LMP. The lower metal pads LMP of the first peripheral circuit area PCA1 correspond to first peripheral circuit pads PCP1. The first peripheral circuit pads PCP1 may be electrically connected to the first peripheral circuits PC1.

The lower metal pads LMP disposed at the surface of the second peripheral circuit area PCA2 of the second semiconductor structure SEMS2 may be electrically connected to the second peripheral circuits PC2. For example, the second peripheral circuit area PCA2 may be an area including the lower metal pads LMP belonging to the seventh row and the eighth row of the matrix array of the lower metal pads LMP. The lower metal pads LMP of the second peripheral circuit area PCA2 correspond to second peripheral circuit pads PCP2. The second peripheral circuit pads PCP2 may be electrically connected to the second peripheral circuits PC2.

The lower metal pads LMP disposed at the surface of the third peripheral circuit area PCA3 of the second semiconductor structure SEMS2 may be electrically connected to the third peripheral circuits PC3. For example, the third peripheral circuit area PCA3 may be an area including the lower metal pads LMP disposed in a common area defined by the third to sixth rows and the fifth to eighth columns of the matrix array of the lower metal pads LMP. The lower metal pads LMP of the third peripheral circuit area PCA3 correspond to third peripheral circuit pads PCP3. The third peripheral circuit pads PCP3 may be electrically connected to the third peripheral circuits PC3.

The first peripheral circuits PC1 may be first bit line sense amplifiers, the second peripheral circuits PC2 may be second bit line sense amplifiers, and the third peripheral circuits PC3 may be sub-word line drivers. The first to third peripheral circuit areas PCA1 to PCA3 may correspond to the peripheral circuit area PCA of FIG. 4.

The lower metal pads LMP disposed at the surface of the unused area UNA of the second semiconductor structure SEMS2 correspond to isolated lower metal pads ILP. For example, the unused area UNA may be an area including the lower metal pads LMP disposed in a common area defined by the third to sixth rows and the first to fourth columns of the matrix array of the lower metal pads LMP. The isolated lower metal pads ILP disposed at the surface of the unused area UNA may not be connected to the first to third peripheral circuits PC1 to PC3 of the second semiconductor structure SEMS2 nor any other circuits of the second semiconductor structure SEMS2. Each of the isolated lower metal pads ILP may form all or part of a corresponding electrical node that is electrically floating.

As described above, a voltage generator may be disposed in the unused area UNA of the second semiconductor structure SEMS2 (e.g., within the footprint of the unused area UNA of the second semiconductor structure SEMS2). The voltage generator may provide internal voltage(s) of one or more voltage levels to each of the first to third peripheral circuits PC1 to PC3.

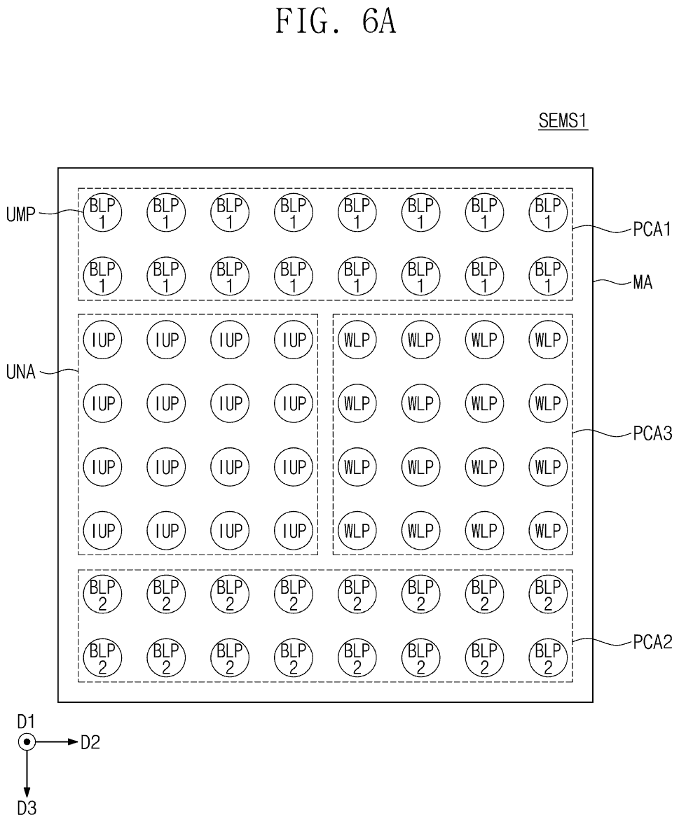

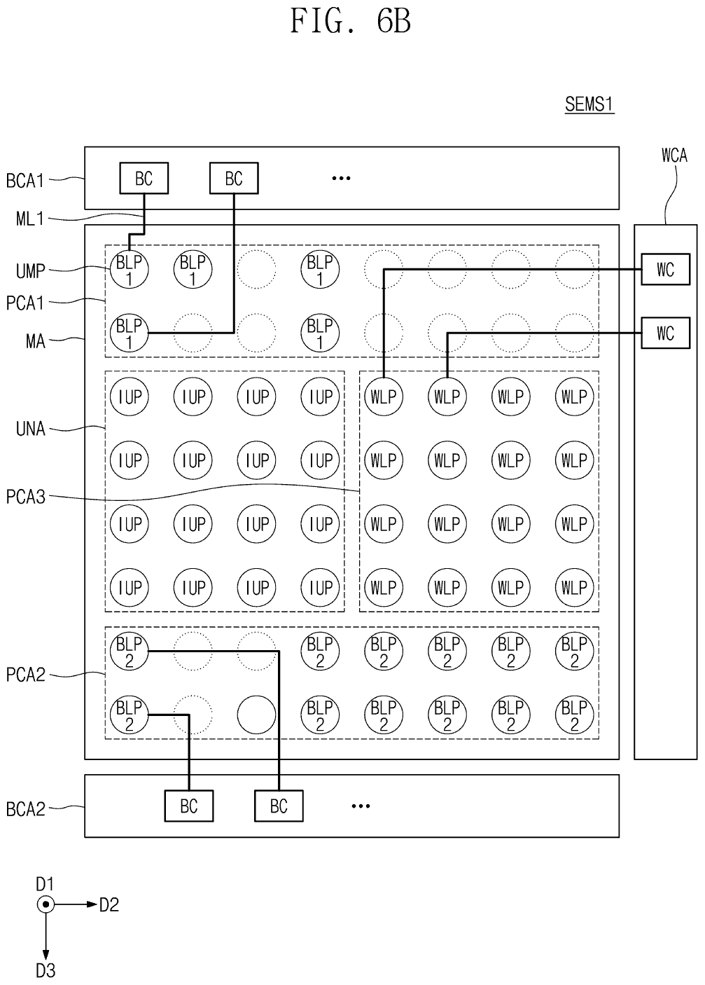

FIGS. 6A and 6B are diagrams illustrating routing of signals in a first semiconductor structure SEMS1 according to an embodiment of the present disclosure. Referring to FIG. 6A, in the memory area MA, the plurality of upper metal pads UMP may be disposed at the surface of the first semiconductor structure SEMS1 in the form of a matrix array including a plurality of rows and a plurality of columns. The placement of the plurality of upper metal pads UMP may be the same as the placement of the plurality of lower metal pads LMP of FIG. 5.

The upper metal pads UMP which are connected to the bit lines may be disposed at a surface of the first semiconductor structure SEMS1, which corresponds to the first peripheral circuit area PCA1. For example, the upper metal pads UMP belonging to the first row and the second row of the matrix array of the upper metal pads UMP may be bit line pads BLP1 connected to some bit lines. The first peripheral circuits PC1 of FIG. 4 may be connected to the bit lines BL through the first peripheral circuit pads PCP1 disposed at the surface of the second semiconductor structure SEMS2, which corresponds to the first peripheral circuit area PCA1, and the bit line pads BLP1 disposed at the surface of the first semiconductor structure SEMS1, which corresponds to the first peripheral circuit area PCA1.

The upper metal pads UMP which are connected to the remaining bit lines may be disposed at a surface of the first semiconductor structure SEMS1, which corresponds to the second peripheral circuit area PCA2. For example, the upper metal pads UMP belonging to the seventh row and the eighth row of the matrix array of the upper metal pads UMP may be bit line pads BLP2 connected to the remaining bit lines BL. The second peripheral circuits PC2 of FIG. 4 may be connected to the bit lines BL through the second peripheral circuit pads PCP2 disposed at the surface of the second semiconductor structure SEMS2, which corresponds to the second peripheral circuit area PCA2, and the bit line pads BLP2 disposed at the surface of the first semiconductor structure SEMS1, which corresponds to the second peripheral circuit area PCA2.

Some of the bit lines BL may be connected to the first peripheral circuits PC1, and the others thereof may be connected to the second peripheral circuits PC2. As described above, each of the first peripheral circuits PC1 and the second peripheral circuits PC2 may include the bit line sense amplifier.

Isolated upper metal pads IUP may be disposed at a surface of the first semiconductor structure SEMS1, which corresponds to the unused area UNA. For example, the unused area UNA may be an area including the upper metal pads UMP disposed in the common area defined by the third to sixth rows and the first to fourth columns of the matrix array of the upper metal pads UMP. The isolated upper metal pads IUP disposed in the unused area UNA may not be connected to the bit lines and the word lines.

Referring to FIG. 6B, the first semiconductor structure SEMS1 may include a first bit line connection area BCA1, a second bit line connection area BCA2, and a word line connection area WCA.

The first bit line connection area BCA1 is placed outside a first side of the memory area MA. The second bit line connection area BCA2 is placed outside a second side of the memory area MA, which faces away from the first side. The word line connection area WCA is placed outside a third side adjacent to the first side and the second side.

A plurality of bit line contacts BC are formed in the first bit line connection area BCA1. The bit line pads BLP1 which correspond to the first peripheral circuit area PCA1 are electrically connected to respective ones of the bit line contacts BC through respective first metal lines ML1. Thus, some of the first metal lines ML1 may be electrically connected to the bit line pads BLP1 and may be electrically connected to some of the bit lines through the bit line contacts BC in the first bit line connection area BCA1.

A plurality of bit line contacts BC are formed in the second bit line connection area BCA2. The bit line pads BLP2 which correspond to the second peripheral circuit area PCA2 are electrically connected to respective ones of the bit line contacts BC through respective first metal lines ML1. Thus, others of the first metal lines ML1 may be electrically connected to the bit line pads BLP2 and may be electrically connected to some of the bit lines through the bit line contacts BC in the second bit line connection area BCA2.

A plurality of word line contacts WC are formed in the word line connection area WCA. Word line pads WLP which correspond to the third peripheral circuit area PCA3 are electrically connected to respective ones of the word line contacts WC through respective first metal lines ML1. That is, the others of the first metal lines ML1 may be electrically connected to the word line pads WLP and may be electrically connected to the word lines through the word line contacts WC in the word line connection area WCA.

The bit line contacts BC formed in the first bit line connection area BCA1 are connected to some of the bit lines BL of the memory cell array, and the bit line contacts BC formed in the second bit line connection area BCA2 are connected to the others of the bit lines BL of the memory cell array. The word lines formed in the word line connection area WCA may be connected to some or all of the word lines of the memory cell array.

The first metal lines ML1 may be formed in one or more metal layers (e.g., portions thereof connected by conductive vias) included in the first semiconductor structure SEMS1.

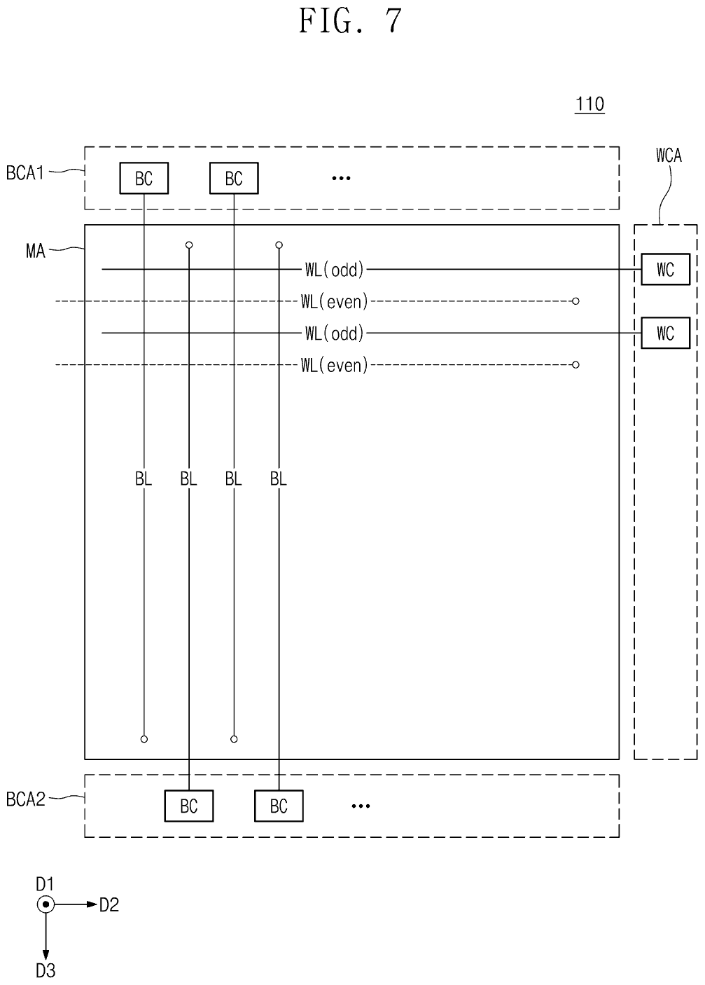

FIG. 7 is a diagram illustrating a memory cell array 110 of a first semiconductor structure SEMS1 according to an embodiment of the present disclosure. Referring to FIG. 7, the plurality of bit lines BL and the plurality of word lines WL may be disposed in the memory area MA. In the memory area MA, the plurality of bit lines BL may be regularly arranged and spaced apart by a first pitch. The plurality of word lines WL may be regularly arranged and spaced apart by a second pitch (which may be the same or different from the first pitch).

A plurality of memory cells (not illustrated) may be disposed at intersections of the plurality of word lines WL and the plurality of bit lines BL.

The bit line contacts BC associated with some of the plurality of bit lines BL are formed in the first bit line connection area BCA1, and the bit line contacts BC associated with the others of the plurality of bit lines BL are formed in the second bit line connection area BCA2. The bit line contacts BC may be formed only outside the memory area MA, such as being arranged along adjacent opposite boundaries of the memory area MA (e.g., the upper and lower boundaries of the memory area MA as shown in FIG. 7). Along a particular boundary of the memory area MA, the bit line contacts BC may be arranged in a single line or in several adjacent lines (e.g., extending in the D2 direction). The word line contacts WC associated with the plurality of word lines WL are formed in the word line connection area WCA. The word line contacts WC may be formed only outside the memory area MA, such as being arranged in one line or several adjacent lines (extending in direction D3) along a boundary of the memory area MA. In FIG. 7, word line contacts WC are shown arranged on just one boundary of the memory area MA, but they may also be arranged along the opposite boundary of the memory area MA in a similar arrangement (i.e., the word line contacts WC may be arranged along both boundaries extending in the D3 direction in FIG. 7).

The first peripheral circuits PC1 included in the second semiconductor structure SEMS2 of FIG. 4 are connected to the lower metal pads LMP disposed in the first peripheral circuit area PCA1 of FIG. 5. The lower metal pads LMP are bonded to the upper metal pads UMP of FIG. 6A so as to be connected electrically and physically. The bonding of the lower metal pads LMP are bonded to the upper metal pads UMP may result in metal of these pads to merge and thus connect the upper and lower semiconductor structures SEMS1 and SEMS2 together. The upper metal pads UMP corresponding to the first peripheral circuit area PCA1 of FIG. 6B are electrically connected to some of the plurality of bit lines BL through the first metal lines ML1 and the bit line contacts BC of the first bit line connection area BCA1. The first peripheral circuits PC1 may operate based on the control signal(s) and the first internal voltage VINT1 provided from the voltage generator 130, and may control some of the plurality of bit lines BL (e.g., selectively provide voltages thereto) during access to memory cells.

The second peripheral circuits PC2 included in the second semiconductor structure SEMS2 of FIG. 4 are connected to the lower metal pads LMP disposed in the second peripheral circuit area PCA2 of FIG. 5. The lower metal pads LMP are bonded to the upper metal pads UMP of FIG. 6A so as to be connected electrically and physically. The upper metal pads UMP corresponding to the second peripheral circuit area PCA2 of FIG. 6B are electrically connected to others of the plurality of bit lines BL through the first metal lines ML1 and the bit line contacts BC of the second bit line connection area BCA2. The second peripheral circuits PC2 may operate based on the control signal(s) and the second internal voltage VINT2 provided from the voltage generator 130, and may control others of the plurality of bit lines BL (e.g., selectively provide voltages thereto) during access to memory cells.

The third peripheral circuits PC3 included in the second semiconductor structure SEMS2 of FIG. 4 are connected to the lower metal pads LMP disposed in the third peripheral circuit area PCA3 of FIG. 5. The lower metal pads LMP are bonded to the upper metal pads UMP of FIG. 6A so as to be connected electrically and physically. The upper metal pads UMP corresponding to the third peripheral circuit area PCA3 of FIG. 6B are electrically connected to the plurality of word lines WL through the first metal lines ML1 and the word line contacts WC of the word line connection area WCA. The third peripheral circuits PC3 may operate based on the control signal(s) and the third internal voltage VINT3 provided from the voltage generator 130, and may control the plurality of word lines WL (e.g., selectively provide voltages thereto) to provide the access to memory cells.

In some examples, some of the plurality of word lines WL disposed in the memory area MA may be electrically connected to the third peripheral circuits PC3. The others of the plurality of word lines WL may be electrically connected to fourth peripheral circuits (i.e., other sub-word line drivers) disposed in another area (which may or may not overlap vertically with the memory area MA), and may be accessed through an operation of the fourth peripheral circuit. Some of the plurality of word lines WL may be odd-numbered word lines WL, and the others of the plurality of word lines WL may be even-numbered word lines WL. The third peripheral circuits PC3 may be an odd-numbered word line drivers connected to odd-numbered word lines WL, and the fourth peripheral circuit may be an even-numbered word line drivers connected to even-numbered word lines WL.

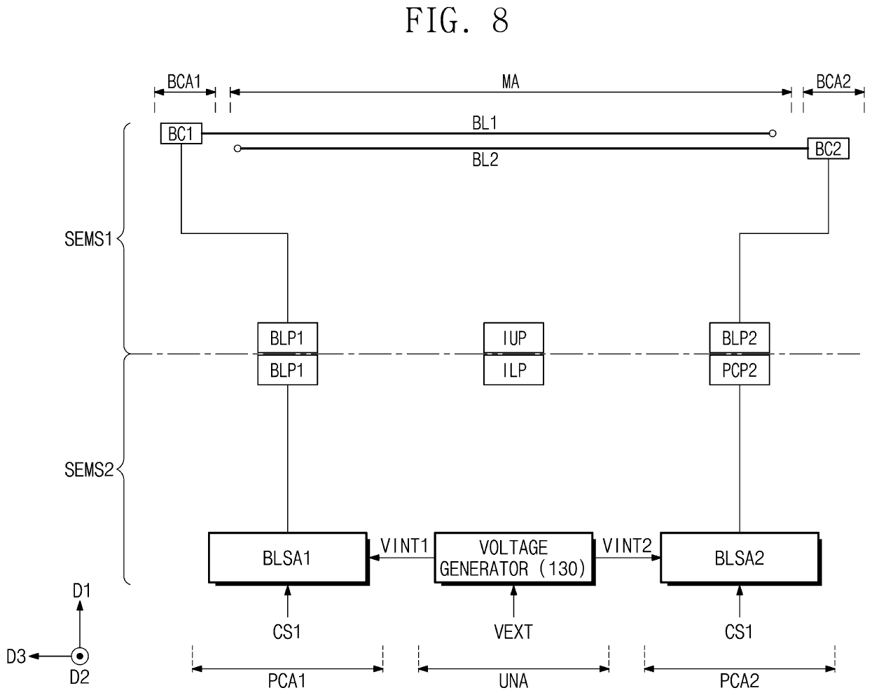

FIG. 8 is a diagram illustrating a connection structure of a vertical cross section in a first direction, according to an embodiment of the present disclosure. Referring to FIG. 8, the voltage generator 130 may provide the first internal voltage VINT1 to the first bit line sense amplifier BLSA1. The voltage generator 130 may provide the second internal voltage VINT2 to the second bit line sense amplifier BLSA2.

The first bit line sense amplifier BLSA1 is disposed in the first peripheral circuit area PCA1 of the second semiconductor structure SEMS2. The first bit line sense amplifier BLSA1 is electrically connected to the first peripheral circuit pad PCP1 among the lower metal pads through at least one metal layer included in the second semiconductor structure SEMS2. The first peripheral circuit pad PCP1 is bonded to the bit line pad BLP1 of the first semiconductor structure SEMS1. That is, the first peripheral circuit pad PCP1 and the bit line pad BLP2 are connected electrically and physically. The bit line pad BLP1 is electrically connected to the bit line contact BC1 formed in the first bit line connection area BCA1 through a metal line formed in at least one metal layer included in the first semiconductor structure SEMS1. The bit line contact BC1 provides the access to a bit line BL1 disposed in the memory area MA. The first bit line sense amplifier BLSA1 may control the bit line BL1 based on a control signal CS1 and the first internal voltage VINT1 and may sense and amplify a voltage of the bit line BL1.

The second bit line sense amplifier BLSA2 is disposed in the second peripheral circuit area PCA2 of the second semiconductor structure SEMS2. The second bit line sense amplifier BLSA2 is electrically connected to the second peripheral circuit pad PCP2 among the plurality of lower metal pads through at least one metal layer included in the second semiconductor structure SEMS2. The second peripheral circuit pad PCP2 is bonded to the bit line pad BLP2 of the first semiconductor structure SEMS1. That is, the second peripheral circuit pad PCP2 and the bit line pad BLP2 are connected electrically and physically. The bit line pad BLP2 is electrically connected to the bit line contact BC2 formed in the second bit line connection area BCA2 through a metal line formed in at least one metal layer included in the first semiconductor structure SEMS1. The bit line contact BC2 provides the access to a bit line BL2 disposed in the memory area MA. The second bit line sense amplifier BLSA2 may control the bit line BL2 based on a control signal CS2 and the second internal voltage VINT2 and may sense and amplify a voltage of the bit line BL2. The bit line BL2 may be disposed in the same plane as the bit line BL1.

The voltage generator 130 is disposed in the unused area UNA of the second semiconductor structure SEMS2. The voltage generator 130 may convert the external voltage VEXT received from the outside of the semiconductor memory device 100 into the first internal voltage VINT1 and the second internal voltage VINT2. The voltage generator 130 may provide the first internal voltage VINT1 to the first bit line sense amplifier BLSA1 and may provide the second internal voltage VINT2 to the second bit line sense amplifier BLSA2.

The first peripheral circuit area PCA1, the second peripheral circuit area PCA2, and the unused area UNA are located in the lower-side area of the memory area MA. The unused area UNA is adjacent to the first peripheral circuit area PCA1 and the second peripheral circuit area PCA2. The voltage generator 130 may be disposed in the unused area UNA, may provide the first internal voltage VINT1 to the first bit line sense amplifier BLSA1 disposed in the first peripheral circuit area PCA1 adjacent thereto, and may provide the second internal voltage VINT2 to the second bit line sense amplifier BLSA2 disposed in the second peripheral circuit area PCA2 adjacent thereto. The voltage generator 130 may provide the internal voltages VINT1 and VINT2 to the first and second bit line sense amplifiers BLSA1 and BLSA2 at a relatively close location, respectively. In this case, compared to the case where the internal voltages VINT1 and VINT2 are respectively provided to the first and second bit line sense amplifiers BLSA1 and BLSA2 from a location outside of the memory area MA, the voltage generator 130 may more stably power the first and second bit line sense amplifiers BLSA1 and BLSA2, and thus, the transient voltage dips may be improved. That is, even though a large amount of power is transiently used by the first and second bit line sense amplifiers BLSA1 and BLSA2, the voltages which are supplied to the first and second bit line sense amplifiers BLSA1 and BLSA2 may be stably maintained.

Meanwhile, the voltage generator 130 may provide the first internal voltage VINT1 to the first bit line sense amplifier BLSA1. Likewise, the voltage generator 130 may provide the second internal voltage VINT2 to the second bit line sense amplifier BLSA2.

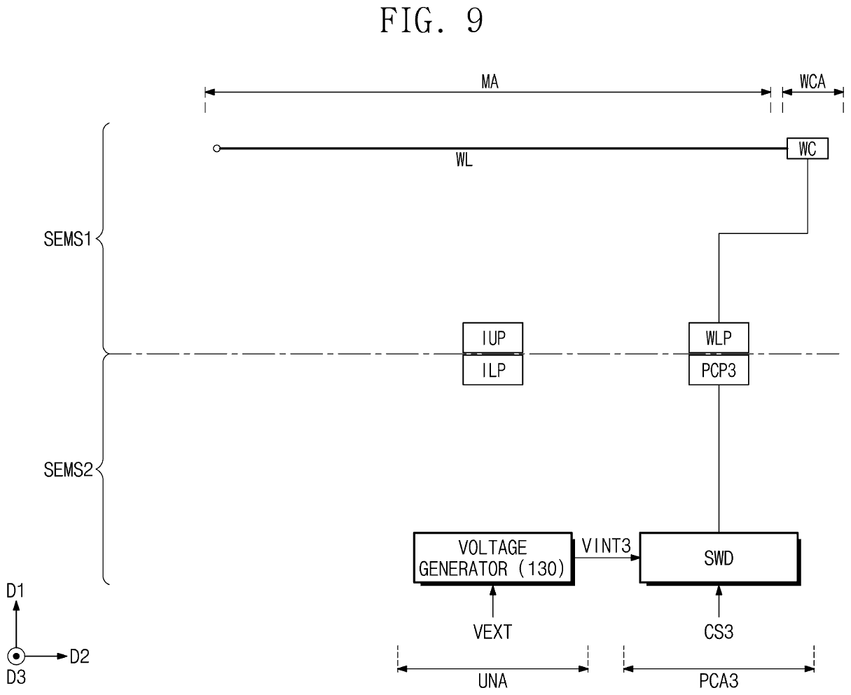

FIG. 9 is a diagram illustrating a connection structure of a vertical cross section in a second direction, according to an embodiment of the present disclosure. Referring to FIG. 9, the voltage generator 130 may provide the third internal voltage VINT3 to the sub-word line driver SWD.

The sub-word line driver SWD is disposed in the third peripheral circuit area PCA3 of the second semiconductor structure SEMS2. The sub-word line driver SWD is electrically connected to the third peripheral circuit pad PCP3 among the plurality of lower metal pads through at least one metal layer included in the second semiconductor structure SEMS2. The third peripheral circuit pad PCP3 is bonded to the word line pad WLP of the first semiconductor structure SEMS1. That is, the third peripheral circuit pad PCP3 and the word line pad WLP are connected electrically and physically. The word line pad WLP is electrically connected to the word line contact WC formed in the word line connection area WCA through a metal line formed in at least one metal layer included in the first semiconductor structure SEMS1. The word line contact WC provides the access to the word line WL disposed in the memory area MA. The sub-word line driver SWD may drive the word line WL based on a control signal CS3 and the third internal voltage VINT3.

The third peripheral circuit area PCA3 and the unused area UNA are located in the portion of the second semiconductor structure SEMS2 below the memory area MA of the semiconductor structure SEMS1. The unused area UNA is adjacent to the third peripheral circuit area PCA3. The voltage generator 130 may be disposed in the unused area UNA and may provide the third internal voltage VINT3 including one or more voltage levels to the sub-word line driver SWD disposed in the third peripheral circuit area PCA3 adjacent thereto. The voltage generator 130 may provide the internal voltage VINT3 to the sub-word line driver SWD at a relatively close location. In this case, compared to the case where the internal voltage VINT3 is provided to the sub-word line driver SWD from the outside of the memory area MA, the voltage generator 130 may stably power the sub-word line driver SWD, and thus, the transient voltage dips may be improved. That is, even though a large amount of power is transiently used by the sub-word line driver SWD, the voltage which is supplied to the sub-word line driver SWD may be stably maintained.

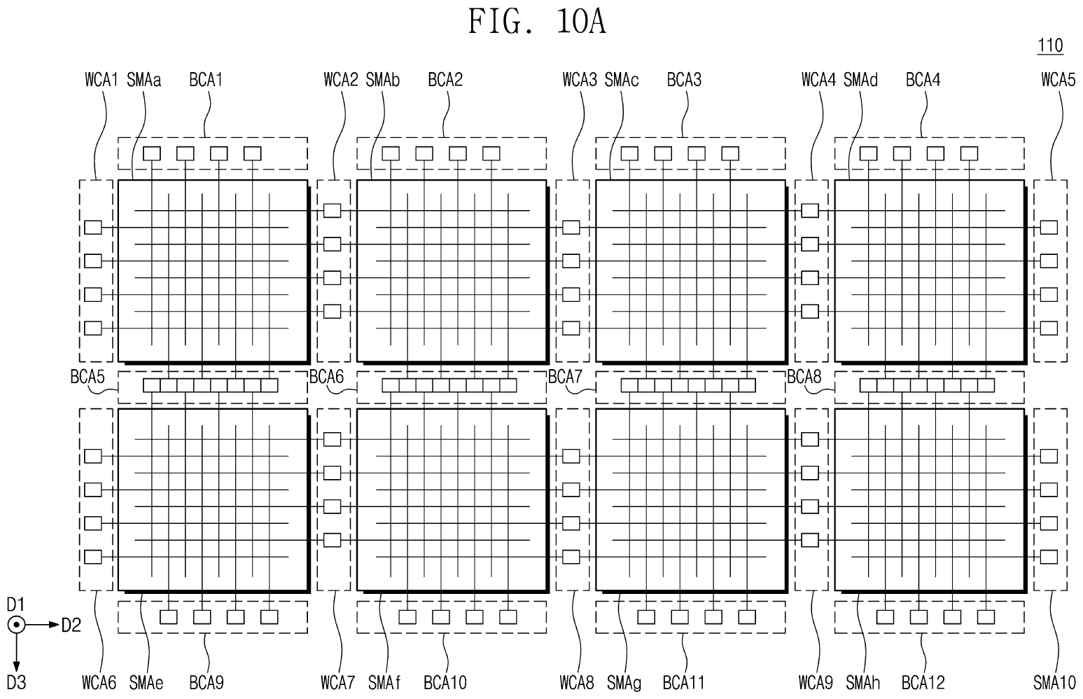

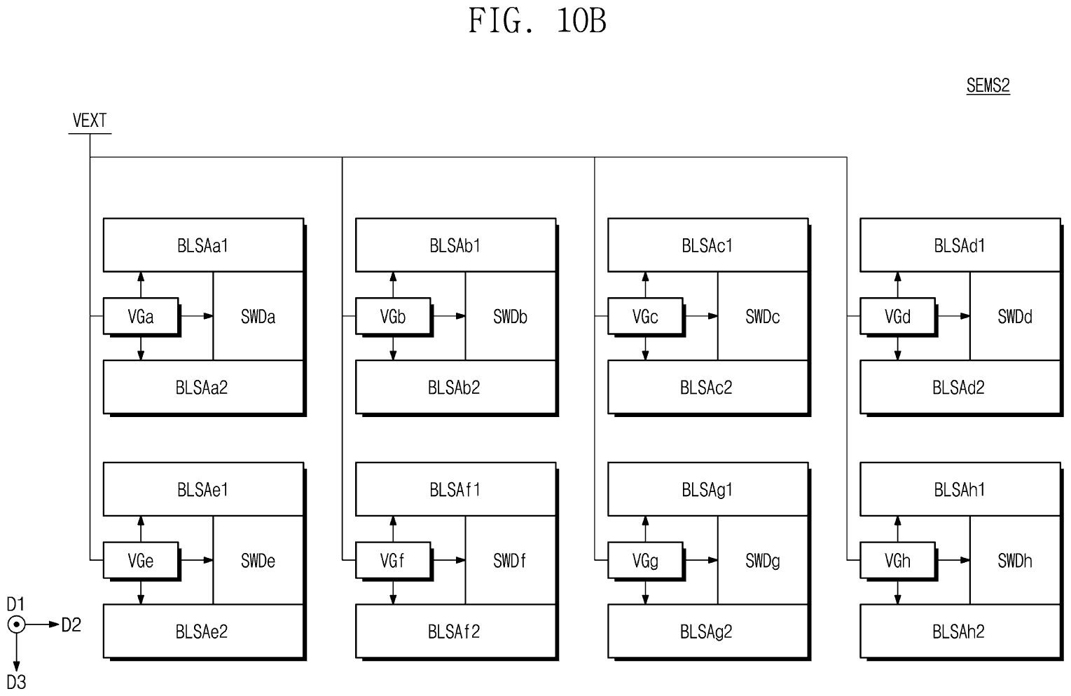

FIGS. 10A and 10B are diagrams illustrating placement of a memory cell array and a peripheral circuit according to an embodiment of the disclosure concept. Referring to FIG. 10A, the memory cell array 110 may include a plurality of sub-memory cell arrays SMAa, SMAb, . . . , SMAh. In some examples, each of the sub-memory cell arrays SMAa, SMAb, . . . , SMAh may be the same as the memory cell array MA described herein with respect to first semiconductor structure SEMS1 (although they may be formed on and/or in (e.g. share) a single semiconductor substrate 210). In some examples, the peripheral circuits and voltage generator formed under each sub-memory cell arrays SMAa, SMAb, . . . , SMAh may be the same as described herein with respect to second semiconductor structure SEMS2 (e.g., same as voltage generator 130 and peripheral circuits 120, PC1, PC2, PC3) (although they may be formed on and/or in (e.g. share) a single semiconductor substrate 220).

In each of the plurality of sub-memory cell arrays SMAa to SMAh, a plurality of word lines may be arranged in a second direction D2, and a plurality of bit lines may be arranged in a third direction D3. Each of the plurality of sub-memory cell arrays SMAa to SMAh may include memory cells formed at intersections of the plurality of word lines and the plurality of bit lines.

The plurality of sub-memory cell arrays SMAa to SMAh may be arranged in the form of a matrix array. For example, the plurality of sub-memory cell arrays SMAa to SMAh may be disposed at two rows and four columns. As an embodiment the plurality of sub-memory cell arrays SMAa to SMAd may be disposed at the first row, and the plurality of sub-memory cell arrays SMAe to SMAh may be disposed at the second row.

Word line connection areas WCA1, WCA2, . . . , WCA5 may be located in in-between areas of the sub-memory cell arrays SMAa to SMAd belonging to the first row and in outer areas of the sub-memory cell arrays SMAa to SMAd belonging to the first row. For example, the first word line connection area WCA1 may be located in an outer area of one side of the sub-memory cell array SMAa, and the fifth word line connection area WCA5 may be located in an outer area of one side of the sub-memory cell array SMAd, which faces away from the one side of the sub-memory cell array SMAa. The second word line connection area WCA2, the third word line connection area WCA3, and the fourth word line connection area WCA4 may be located in in-between areas of the sub-memory cell arrays SMAa to SMAd belonging to the first row.

As in the sub-memory cell arrays SMAa to SMAd belonging to the first row, word line connection areas WCA6, WCA7, . . . , WCA10 may be located in in-between areas of the sub-memory cell arrays SMAe to SMAh belonging to the second row and in outer areas of the sub-memory cell arrays SMAe to SMAh belonging to the second row.

The sub-memory cell array SMAa and the sub-memory cell array SMAe may be located at the first column. The first bit line connection area BCA1 may be located on the outside of one side of the sub-memory cell array SMAa. The fifth bit line connection area BCA5 may be located in an in-between area of the sub-memory cell array SMAa and the sub-memory cell array SMAe. A ninth bit line connection area BCA9 may be located on the outside of one side of the sub-memory cell array SMAe, which faces away from the one side of the sub-memory cell array SMAa. As in the first column, bit line connection areas BCA2, BC3, BCA4, BCA6, BCA7, BCA8, BCA10, BCA11, and BCA12 may be located at the second column to the fourth column.

Word line contacts of some of the word lines disposed in the sub-memory cell array SMAa may be formed in the first word line connection area WCA1. Word line contacts of the others of the word lines disposed in the sub-memory cell array SMAa may be formed in the second word line connection area WCA2. For example, word line contacts of even-numbered word lines disposed in the sub-memory cell array SMAa may be formed in the first word line connection area WCA1, and word line contacts of odd-numbered word lines disposed in the sub-memory cell array SMAa may be formed in the second word line connection area WCA2. The even-numbered word lines and the odd-numbered word lines may be alternately disposed in the sub-memory cell array SMAa.

The word line contacts formed in the second word line connection area WCA2 may provide the access to the word lines disposed in the sub-memory cell array SMAb, as well as the access to the word lines disposed in the sub-memory cell array SMAa. For example, odd-numbered word lines among the word lines disposed in the sub-memory cell array SMAb may be connected to the word line contacts of the second word line connection area WCA2. That is, the odd-numbered word lines disposed in the sub-memory cell array SMAa and the odd-numbered word lines disposed in the sub-memory cell array SMAb may share the word line contacts formed in the second word line connection area WCA2. As in the above description, even-numbered word lines disposed in the sub-memory cell array SMAb and even-numbered word lines disposed in the sub-memory cell array SMAc may share word line contacts formed in the third word line connection area WCA3.

Bit line contacts of some of the bit lines disposed in the sub-memory cell array SMAa may be formed in the first bit line connection area BCA1. Bit line contacts of the others of the bit lines disposed in the sub-memory cell array SMAa may be formed in the fifth bit line connection area BCA5. Bit line contacts of some of the bit lines disposed in the sub-memory cell array SAMe may be formed in the fifth bit line connection area BCA5, and bit line contacts of the others of the bit lines disposed in the sub-memory cell array SMAe may be formed in the ninth bit line connection area BCA9.

Referring to FIG. 10B, peripheral circuits and a voltage generator may be disposed below each of the plurality of sub-memory cell arrays SMAa to SMAh. The peripheral circuits may include first bit line sense amplifiers, second bit line sense amplifiers, and sub-word line drivers. The external voltage(s) VEXT may be applied to voltage generators VGa, VGb, . . . , VGh. Each of the voltage generators VGa, VGb, . . . , VGh may convert the external voltage(s) VEXT into one or more internal voltages to be used by the peripheral circuits. Each of the voltage generators VGa, VGb, . . . , VGh may provide internal voltages which may have one or more voltage levels to the peripheral circuits.

For example, the voltage generator VGa may provide internal voltages including one or more voltage levels to each of first bit line sense amplifiers BLSAa1, second bit line sense amplifiers BLSAa2, and sub-word line drivers SWDa. As in the above description, each of the voltage generators VGb to VGh may similarly provide internal voltages including one or more voltage levels to peripheral circuits adjacent thereto.

The first bit line sense amplifiers BLSAa1 may be connected to some of the bit lines disposed in the sub-memory cell array SMAa through metal lines, metal pads, and bit line contacts formed in the first bit line connection area BCA1. First bit line sense amplifiers BLSAa1 may control some of the bit lines disposed in the sub-memory cell array SMAa based on control signal(s) and the internal voltage provided from the voltage generator VGa.

The second bit line sense amplifiers BLSAa2 may be connected to the others of the bit lines disposed in the sub-memory cell array SMAa through metal lines, metal pads, and bit line contacts formed in the fifth bit line connection area BCA5. Second bit line sense amplifiers BLSAa2 may control the others of the bit lines disposed in the sub-memory cell array SMAa based on control signal(s) and the internal voltage provided from the voltage generator VGa.

The sub-word line drivers SWDa may be connected to the odd-numbered word lines among the word lines disposed in the sub-memory cell array SMAa through metal lines, metal pads, and word line contacts formed in the second word line connection area WCA2. The sub-word line drivers SWDa may drive the odd-numbered word lines disposed in the sub-memory cell array SMAa based on control signal(s) and the internal voltage provided from the voltage generator VGa. In this case, the sub-word line driver SWDa may further drive the odd-numbered word lines disposed in the sub-memory cell array SMAb sharing the word line contacts with the odd-numbered word lines disposed in the sub-memory cell array SMAa.

The sub-word line drivers SWDb may be connected to the even-numbered word lines disposed in the sub-memory cell array SMAb and the sub-memory cell array SMAc through metal lines, metal pads, and word line contacts formed in the third word line connection area WCA3. The sub-word line drivers SWDb may drive the even-numbered word lines disposed in the sub-memory cell array SMAb and the sub-memory cell array SMAc based on control signal(s) and the internal voltage provided from the voltage generator VGb.

The voltage generators VGa to VGh are respectively disposed in the lower-side areas of the sub-memory cell arrays SMAa to SMAh. Each of the voltage generators VGa to VGh may provide internal voltage(s) to adjacent peripheral circuits as described herein with respect to voltage generator VGa and 130. As each of the voltage generators VGa to VGh provides the internal voltage to the adjacent peripheral circuits, the influence of the transient voltage dips between peripheral circuits may be reduced, and the internal voltage which are used by the peripheral circuits may be stably maintained.

The sub-memory cell arrays SMAa to SMAh and the peripheral circuits of FIGS. 10A and 10B may be in the shape of a matrix with two rows and four columns, but this is an example. The number of rows of sub-memory cell arrays constituting the memory cell array 110 may be more or less.

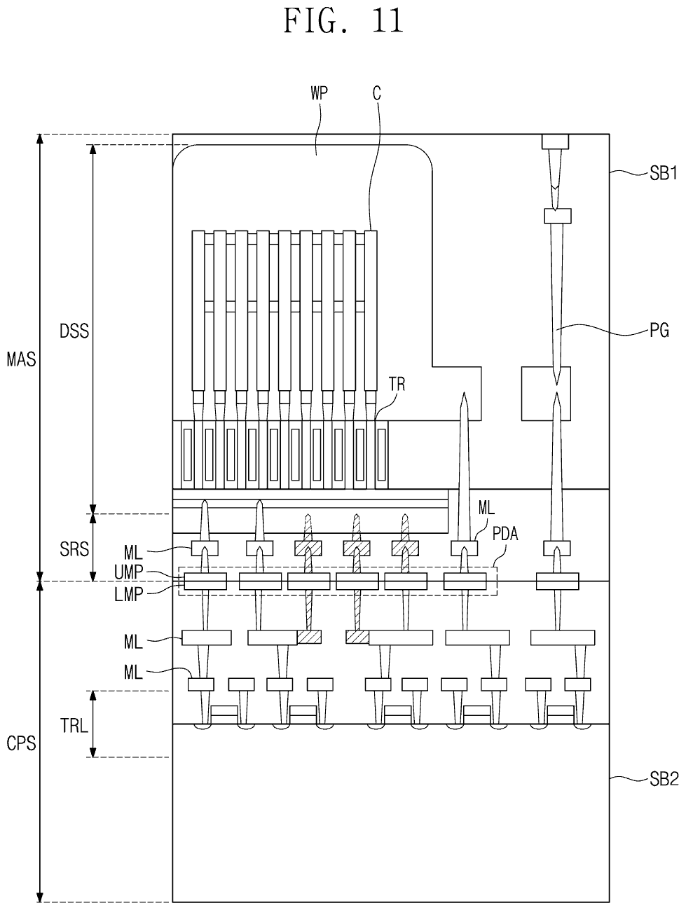

FIG. 11 is a diagram illustrating details of an integrated circuit device, which may be embodied by the semiconductor memory devices described herein. Referring to FIG. 11, an integrated circuit device may include a memory cell array structure MAS and a core-peripheral circuit structure CPS. The integrated circuit device may be a semiconductor chip formed as a core over peripheral (CoP) structure.

The memory cell array structure MAS may be formed on a first substrate SB1 (e.g., a semiconductor substrate). The memory cell array structure MAS may include a data storage structure DSS and a signal routing structure SRS. The data storage structure DSS may include a plurality of memory cells each including a capacitor “C” and a cell transistor TR (e.g., DRAM cells), a plurality of bit lines, and a plurality of word lines. The signal routing structure SRS may include the plurality of upper metal pads UMP and a plurality of metal lines ML. The plurality of metal lines ML electrically connect the plurality of upper metal pads UMP and components of the data storage structure DSS. For example, the plurality of metal lines ML may electrically connect some of the plurality of upper metal pads UMP and the bit lines. Also, the plurality of metal lines ML may electrically connect some of the plurality of upper metal pads UMP and the word lines.

The core-peripheral circuit structure CPS may be formed on a second substrate SB2. The core-peripheral circuit structure CPS may include a transistor layer TRL. Various kinds of elements including a plurality of transistors for controlling or driving the bit lines and the word lines included in the data storage structure DSS may be disposed in the transistor layer TRL. Some of the plurality of elements disposed in the transistor layer TRL may be included in a bit line sense amplifier. Others of the plurality of elements disposed in the transistor layer TRL may be included in a sub-word line driver. The others of the plurality of elements disposed in the transistor layer TRL may be included in a voltage generator.

The plurality of lower metal pads LMP may be disposed at the surface of the core-peripheral circuit structure CPS. Some or all of the plurality of lower metal pads LMP may be electrically connected to a plurality of peripheral circuits disposed in the transistor layer TRL through the plurality of metal lines ML.

The plurality of the upper metal pads UMP and the plurality of lower metal pads LMP may be disposed in the same matrix array form and provide the electrical connection of each component included in the memory cell array structure MAS and each component included in the core-peripheral circuit structure CPS. The plurality of upper metal pads UMP and the plurality of lower metal pads LMP may constitute a pad array PDA.

Meanwhile, an unused area may be located below a portion of a memory area where the plurality of word lines and the plurality of bit lines are disposed. The upper metal pads UMP corresponding to the unused area may not be connected to the bit lines and the word lines. The lower metal pads LMP corresponding to the unused area may not be connected to the bit line sense amplifier and the sub-word line driver. The voltage generator may be disposed in one area of the transistor layer TRL, which corresponds to the unused area. The voltage generator may provide an internal voltage to an adjacent bit line sense amplifier or an adjacent sub-word line driver.

One or more plugs PG provide the electrical connections between the core-peripheral circuit structure CPS and devices external to the integrated circuit device. Command signals, address signals, data signals, and external power may be input to the core-peripheral circuit structure CPS through the one or more plugs PG.

In the integrated circuit device, because the memory cell array structure MAS and the core-peripheral circuit structure CPS are vertically disposed, the area on the plane may be reduced compared to the case where a memory cell array and peripheral circuits are disposed in one plane.

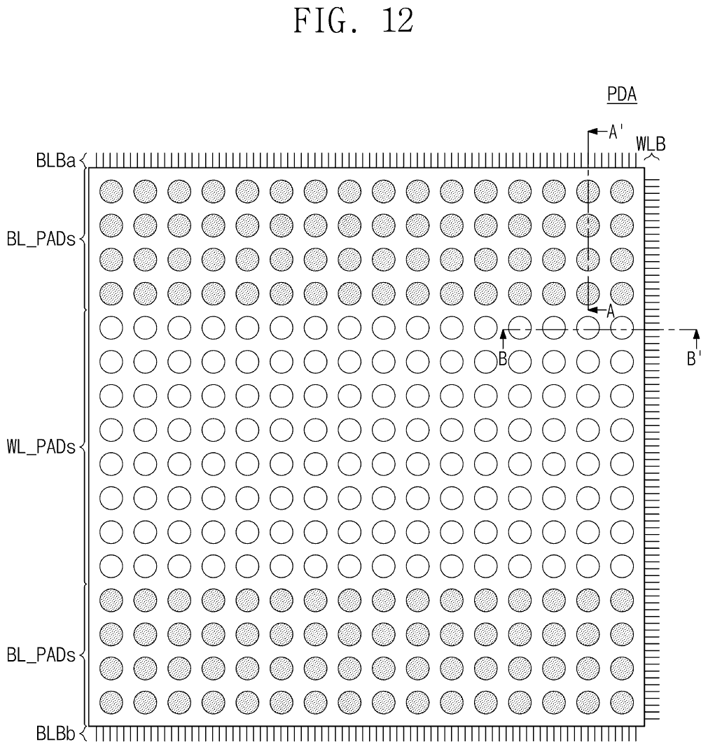

FIG. 12 is a diagram illustrating an array of pads of the integrated circuit device of FIG. 11. Referring to FIG. 12, the pad array PDA may include a plurality of bit line pads BL_PADs and a plurality of word line pads WL_PADs. The pad array PDA corresponds to the plurality of upper metal pads UMP illustrated in FIG. 11. The lower metal pads LMP of FIG. 11 may be disposed to have the same layout as the upper metal pads UMP.

The plurality of bit line pads BL_PADs may be disposed in a first peripheral region of the plane and a second peripheral region of the plane, which faces away from the first peripheral region. The plurality of bit line pads BL_PADs may be electrically connected to a bit line connection region BLB through one or more metal layers. Signals received through the plurality bit line pads BL_PADs disposed in the first peripheral region may be routed to a bit line connection area BLBa outside the first peripheral region, and signals received through the plurality of bit line pads BL_PADs disposed in the second peripheral region may be routed to a bit line connection area BLBb outside the second peripheral region.

The bit line connection areas BLBa and BLBb may provide the electrical connection of the plurality of bit line pads BL_PADs and the bit lines included in the memory cell array (e.g., as described elsewhere herein). A word line connection area WLB may provide the electrical connection of the plurality of word line pads WL_PADs and the word lines included in the memory cell array (e.g., as described elsewhere herein).

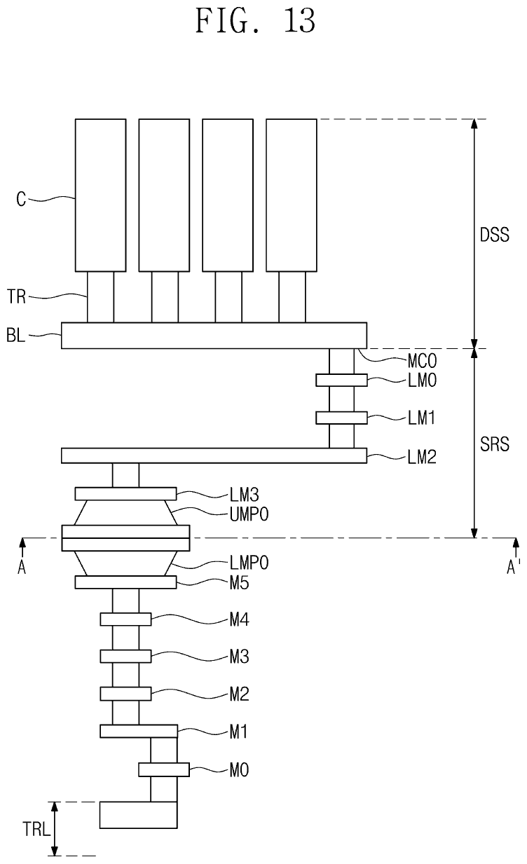

FIG. 13 is a diagram illustrating a vertical cross section of an integrated circuit device taken along line A-A′ of FIG. 12. Referring to FIG. 13, a bit line sensing amplifier disposed in the transistor layer TRL may be electrically connected to a bit line BL.

Certain components (e.g., neighboring metal pads) are not shown for clarity and repetitive description may be omitted.

The data storage structure DSS may include the plurality of capacitors “C”, the cell transistors TR, and the plurality of bit lines BL. The signal routing structure SRS is an example of a metal line ML described herein and may include portions of the plurality of metal layers LM0 to LM3 and an upper metal pad UMP0. The routing shown may be simplified and other patterns may be formed in the metal layers to form the routing structure/metal line ML.

The bit line sense amplifier circuit disposed in the transistor layer TRL may be connected to a lower metal pad LMP0 through metal layers M0, M1, M2, M3, M4, and M5 (which form another example of a metal line ML described herein). The lower metal pad LMP0 may be bonded to the upper metal pad UMP0. That is, the lower metal pad LMP0 may be physically and electrically connected to the upper metal pad UMP0. The upper metal pad UMP0 may be electrically connected to the portions of plurality of metal layers LM3, LM2, LM1, and LM0. The metal layer LM0 may be electrically connected to the bit line BL through a metal contact MC0. The metal contact MC0 may be formed in the bit line connection area BLB of FIG. 12. The change in a potential of the bit line BL by the capacitor “C” and the cell transistor TR is transferred to the transistor layer TRL through the plurality of metal line formed by portions of LM0 to LM3, the upper metal pad UMP0, the lower metal pad LMP0, and the portions of plurality of metal layers M0 to M5. The bit line sense amplifier disposed in the transistor layer TRL may sense and amplify data stored in the capacitor “C” by amplifying a difference in the potential of the bit line BL and the potential of a complementary bit line (to which the bit line sense amplifier is also connected in a similar manner (not shown)).

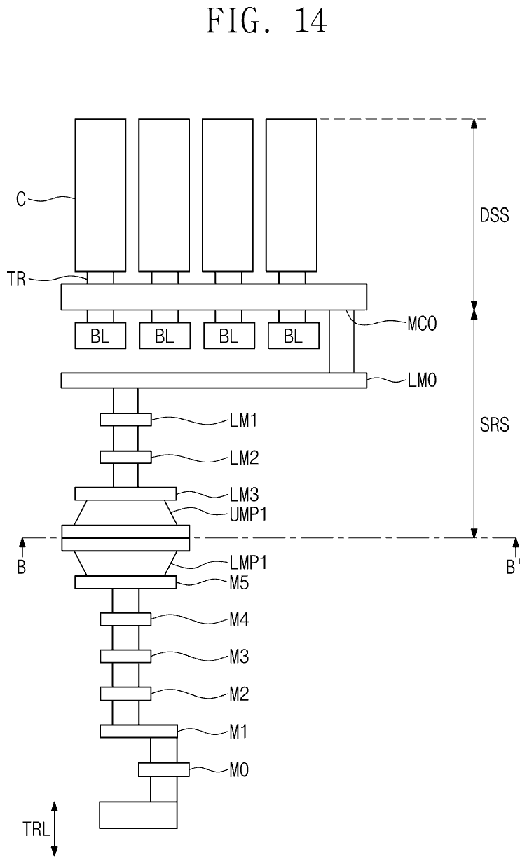

FIG. 14 is a diagram illustrating a vertical cross section of an integrated circuit device taken along line B-B′ of FIG. 12. Referring to FIG. 14, a sub-word line driver disposed in the transistor layer TRL may be electrically connected to a word line WL.

Certain components (e.g., neighboring metal pads) are not shown for clarity and repetitive description may be omitted.

The data storage structure DSS may include the plurality of capacitors “C”, the cell transistors TR, the plurality of bit lines BL, and the plurality of word lines WL. The signal routing structure SRS is an example of a metal line ML described herein and may include portions of the plurality of metal layers LM0 to LM3 and an upper metal pad UMP1. The sub-word line driver disposed in the transistor layer TRL may be connected to the lower metal pad LMP1 through the metal layers M0, M1, M2, M3, M4, and M5 (forming another example of a metal line ML described herein). The lower metal pad LMP1 may be bonded to the upper metal pad UMP1. That is, the lower metal pad LMP1 may be physically and electrically connected to the upper metal pad UMP1. The upper metal pad UMP1 may be electrically connected to the portions of the plurality of metal layers LM3, LM2, LM1, and LM0. The metal layer LM0 may be electrically connected to the word line WL through the metal contact MC0. The metal contact MC0 may be formed in the word line connection area WLB of FIG. 12. A word line driving voltage which the sub-word line driver outputs is applied to the word line WL through the portions of plurality of metal layers M0 to M5, the lower metal pad LMP1, the upper metal pad UMP1, the portions of plurality of metal layers LM0 to LM3, and the metal contact MC0. The cell transistor TR may be switched by the word line driving voltage applied to the word line WL, and thus, the bit line BL and the capacitor “C” are connected.

As described above, a semiconductor memory device according to embodiments of the present disclosure may include a voltage generator which is disposed in an area below a memory cell array and supplies an internal voltage to adjacent peripheral circuits. As the voltage generator supplies the internal voltage to the peripheral circuits at a relatively close location, the transient voltage dips which are caused when power consumption of the peripheral circuits transiently increases may be improved.

In a semiconductor memory device according to embodiments of the present disclosure, a memory cell array is disposed in a memory area of a first semiconductor substrate, and a peripheral circuit and a voltage generator are disposed in a second semiconductor substrate bonded to the first semiconductor substrate through metal pads. The peripheral circuit and the voltage generator are disposed under (or on a lower side of) the memory area to be adjacent to each other. Accordingly, the voltage generator may stably provide a voltage to the peripheral circuit, and the degree of integration of the semiconductor memory device may be improved.

While the present invention has been described with reference to embodiments thereof, it will be apparent to those of ordinary skill in the art that various changes and modifications may be made thereto without departing from the spirit and scope of the present invention.

What is claimed is:

1. A semiconductor memory device comprising:
a first semiconductor structure including a first semiconductor substrate, a memory cell array, and a plurality of upper metal pads, the memory cell array being formed in a memory area of the first semiconductor substrate and including bit lines and word lines; and
a second semiconductor structure disposed below the first semiconductor structure including a second semiconductor substrate, a plurality of lower metal pads respectively bonded to the plurality of upper metal pads, a peripheral circuit disposed under the memory area, a voltage generator positioned below the memory area to provide an internal voltage to the peripheral circuit,
wherein the bit lines and the word lines are electrically connected to corresponding ones of the upper metal pads, and
wherein some or all of the lower metal pads are electrically connected to terminals of the peripheral circuit.

2. The semiconductor memory device of claim 1,
wherein the lower metal pads include first lower metal pads electrically connected to the peripheral circuit and second lower metal pads that are dummy pads, and
wherein the voltage generator is disposed under the second lower metal pads.

3. The semiconductor memory device of claim 1, wherein the peripheral circuit includes first bit line sense amplifiers, second bit line sense amplifiers, and sub-word line drivers.

4. The semiconductor memory device of claim 3, wherein the first bit line sense amplifiers are disposed in a first peripheral area under a first side of the memory cell array, the second bit line sense amplifiers are disposed in a second peripheral area under a second side of the memory cell array that is opposite to the first side of the memory cell array, and the sub-word line drivers are disposed under a third side of the memory cell array between the first peripheral area and the second peripheral area.

5. The semiconductor memory device of claim 4, wherein the voltage generator provides an internal voltage to at least one of the first bit line sense amplifiers, the second bit line sense amplifiers, and the sub-word line drivers.

6. The semiconductor memory device of claim 1, wherein the first semiconductor structure includes a first bit line connection area, a second bit line connection area, and a word line connection area.

7. The semiconductor memory device of claim 6, wherein the first bit line connection area is located outside and along a first side of the memory cell array, the second bit line connection area is located outside and along a second side of the memory cell array that is opposite to the first side of the memory cell array, and the word line connection area is located outside and along a third side of the memory cell array that extends between the first side and the second side.

8. The semiconductor memory device of claim 7, wherein the first semiconductor structure includes a first metal line connected to a corresponding one of the upper metal pads, and a bit line contact electrically connecting a corresponding one of the bit lines and the first metal line in the first bit line connection area.

9. The semiconductor memory device of claim 8, wherein the first semiconductor structure further includes a second metal line connected to a corresponding one of the upper metal pads, and a word line contact electrically connecting a corresponding one of the word lines and the second metal line in the word line connection area.

10. A semiconductor memory device comprising:
a first semiconductor structure including a first semiconductor substrate, a plurality of sub-memory cell arrays arranged in two dimensions and a plurality of upper metal pads; and
a second semiconductor structure disposed below the first semiconductor structure,
wherein the second semiconductor structure includes:
a second semiconductor substrate;
a plurality of lower metal pads bonded to the plurality of upper metal pads;
a plurality of peripheral circuits respectively disposed below and electrically connected to respective ones of the plurality of sub-memory cell arrays; and
a plurality of voltage generators each disposed below a respective one of the plurality of sub-memory cell arrays to provide an internal voltage to the corresponding peripheral circuit.

11. The semiconductor memory device of claim 10, wherein each of the peripheral circuits includes first bit line sense amplifiers, second bit line sense amplifiers, and sub-word line drivers.

12. The semiconductor memory device of claim 11, wherein first bit line sense amplifiers corresponding to a first sub-memory cell array among the plurality of sub-memory cell arrays are disposed in a first peripheral area under a first side of the first sub-memory cell array, second bit line sense amplifiers corresponding to the first sub-memory cell array are disposed in a second peripheral area under a second side of the first sub-memory cell array that faces the first side of the first sub-memory cell array, and second sub-word line drivers are disposed in a under a third side of the first sub-memory cell array between the first peripheral area and the second peripheral area.

13. The semiconductor memory device of claim 12, wherein a first voltage generator of the plurality of voltage generators is disposed below the first sub-memory cell array in a first area that is adjacent to the first bit line sense amplifiers on a first side of the first area, the second bit line sense amplifiers on a second side of the first area, and the sub-word line drivers on a third side of the first area.

14. The semiconductor memory device of claim 12,
wherein the first sub-memory cell array comprises a plurality of odd-numbered word lines interleaved with a plurality of even-numbered word lines,
wherein the plurality of sub-memory cell arrays includes a second sub-memory cell array that is adjacent to the first sub-memory cell array in a row direction and includes a plurality of odd-numbered word lines interleaved with a plurality of even-numbered word lines, and
wherein the first sub-word line drivers drive the odd-numbered word lines of the first sub-memory cell array and the odd-numbered word lines of a second sub-memory cell array.

15. The semiconductor memory device of claim 14,
wherein the plurality of sub-memory cell arrays includes a third sub-memory cell array that is adjacent to the second sub-memory cell array in the row direction and includes a plurality of odd-numbered word lines interleaved with a plurality of even-numbered word lines, and
wherein second sub-word line drivers are disposed below the second sub-memory cell array to drive the even-numbered word lines of the second sub-memory cell array and even-numbered word lines of the third sub-memory cell array.

16. The semiconductor memory device of claim 12, wherein the first semiconductor structure further includes a first bit line connection area located along a first side of the first sub-memory cell array that extends in a column direction and a second bit line connection area located along a second side of the first sub-memory cell array that extends in the column direction, the second side of the first sub-memory cell array being opposite to the first side of the first sub-memory cell array.

17. The semiconductor memory device of claim 16,
wherein the first bit line sense amplifiers are electrically connected to corresponding bit line metal contacts formed in the first bit line connection area, and
wherein the second bit line sense amplifiers are electrically connected to corresponding bit line metal contacts formed in the second bit line connection area.

18. A semiconductor memory device comprising:
a first semiconductor substrate;
a memory cell array formed in a memory area of the first semiconductor substrate and including a plurality of word lines and a plurality of bit lines;
a plurality of upper metal pads formed in the memory area arranged in a two dimensional array;
one or more first metal layers electrically connecting first ends of the plurality of word lines or first ends of the plurality of bit lines with corresponding ones of the plurality of upper metal pads;
a second semiconductor substrate disposed below the first semiconductor substrate;
first bit line sense amplifiers formed in an area of the second semiconductor substrate below the memory cell array, and configured to sense and amplify voltages of corresponding ones of the plurality of bit lines;
second bit line sense amplifiers formed in an area of the second semiconductor substrate below the memory cell array, and configured to sense and amplify voltages of corresponding ones of the plurality of bit lines;
sub-word line drivers configured to apply voltages to corresponding ones of the plurality of word lines;
a voltage generator formed in a first area of the second semiconductor substrate below the memory cell array, and configured to provide an internal voltage to at least one of the first bit line sense amplifiers, the second bit line sense amplifiers, and the sub-word line drivers;
a plurality of lower metal pads arranged in a two dimensional array; and
one or more second metal layers electrically connecting the first bit line sense amplifiers, the second bit line sense amplifiers, and the sub-word line drivers with corresponding ones of the plurality of lower metal pads,
wherein the plurality of upper metal pads and the plurality of lower metal pads are bonded together.

19. The semiconductor memory device of claim 18, wherein the first bit line sense amplifiers are disposed in a first peripheral area under a first side of the memory cell array, the second bit line sense amplifiers are disposed in a second peripheral area under a second side of the memory cell array that is opposite to the first side of the memory cell array, and the sub-word line drivers are disposed in a third peripheral circuit area between the first peripheral area and the second peripheral area.

20. The semiconductor memory device of claim 19, wherein the first area is adjacent to each of the first peripheral area, the second peripheral area, and the third peripheral circuit area.
